(19) United States
(12) Patent Application Publication
(10) Pub. No.: US 2025/0080080 A1
(43) Pub. Date: Mar. 6, 2025

(54) ACOUSTIC WAVE DEVICE AND MODULE

(71) Applicant: Sanan Japan Technology Corporation, Tokyo (JP)

(72) Inventors: Yoshiaki Takaoka, Tokyo (JP); Shinichi Shioi, Tokyo (JP)

(73) Assignee: Sanan Japan Technology Corporation, Tokyo (JP)

(21) Appl. No.: 18/814,277

(22) Filed: Aug. 23, 2024

(30) Foreign Application Priority Data
Aug. 28, 2023 (JP) 2023-137854

(51) Int. Cl. H03H 9/145; H03H 9/02; H03H 9/05; H03H 9/10; H03H 9/25

(52) U.S. Cl. CPC H03H 9/1457; H03H 9/02992; H03H 9/059; H03H 9/1085; H03H 9/25

(57) ABSTRACT

An acoustic wave device includes a piezoelectric substrate, a support substrate bonded to the piezoelectric substrate, and a resonator comprising a plurality of pairs of IDT electrodes arranged side by side that generates main-mode wave and transverse-mode wave when power is applied. The resonator includes a first busbar, a second busbar opposed to the first busbar, a plurality of first electrode fingers connected to a side of the second busbar in the first busbar, a plurality of second electrode fingers connected to a side of the first busbar in the second busbar, a plurality of first dummy electrodes connected to the side of the second busbar in the first busbar and opposed to the plurality of second electrode fingers, and a plurality of second dummy electrodes connected to the side of the first busbar in the second busbar and opposed to the plurality of first electrode fingers.

### CROSS-REFERENCE TO RELATED APPLICATION(S)

This application claims priority to the Japanese Application No. 2023-137854, filed Aug. 28, 2023, which is incorporated herein by reference, in its entirety, for any purpose.

### BACKGROUND OF THE INVENTION

### Field of the Invention

The present disclosure relates to an acoustic wave device and a module including the acoustic wave device.

### Background Art

Patent Document 1 (JP 2018-174595) discloses an acoustic wave device. A wide-width region of the electrode finger or the like is provided in the acoustic wave device. Such a wide-width region can suppress transverse-mode spurious.

However, transverse-mode spurious cannot be sufficiently suppressed by the wide-width regions alone or the like in the acoustic wave device described in Patent Document 1. Therefore, it is desired to more certainly suppress transverse-mode spurious.

### SUMMARY OF THE INVENTION

Some examples described herein may address the above-described problems. Some examples described herein may have an object to provide an acoustic wave device capable of suppressing transverse-mode spurious more effectively, and a module including the acoustic wave device.

In some examples, an acoustic wave device includes a piezoelectric substrate, a support substrate bonded to the piezoelectric substrate, and a multimode resonator comprising a plurality of pairs of IDT electrodes arranged side by side and formed on the other side of the support substrate on the piezoelectric substrate that generates a main-mode wave and a transverse-mode wave when power is applied. At least one of the plurality of IDT electrodes includes a first busbar, a second busbar opposed to the first busbar, a plurality of first electrode fingers connected to the side of the second busbar in the first busbar, a plurality of second electrode fingers connected to the side of the first busbar in the second busbar, a plurality of first dummy electrodes connected to the side of the second busbar in the first busbar and opposed to the plurality of second electrode fingers, and a plurality of second dummy electrodes connected to the side of the first busbar in the second busbar and opposed to the plurality of first electrode fingers. The distal ends of the plurality of first electrode fingers include first distal side wide-width regions, the distal ends of the plurality of second electrode fingers include second distal side wide-width regions, and the lengths of the plurality of first dummy electrodes continuously change from one end portion to the other end portion of the first busbar.

### BRIEF DESCRIPTION OF THE DRAWING

FIG. 1 is a cross-sectional view of an acoustic wave device according to a first embodiment.

FIG. 2 is a schematic diagram illustrating an example of a resonator of the acoustic wave device according to the first embodiment.

FIG. 3 is an enlarged view of a main portion of FIG. 2.

FIG. 4 is an enlarged view of portions E and F of FIG. 3.

FIG. 5 is a diagram illustrating the characteristics of the resonator of the acoustic wave device according to the first embodiment and a resonator of the comparative example.

FIG. 6 is a diagram illustrating the characteristics of a resonator including a busbar with the same inclined section as the resonator of the acoustic wave device according to the first embodiment and the different wide-width regions with the same length of the dummy electrodes.

FIG. 7 is a schematic diagram illustrating an example of a resonator of an acoustic wave device according to a second embodiment.

FIG. 8 is a schematic diagram illustrating an example of a resonator of an acoustic wave device according to a third embodiment.

FIG. 9 is a schematic diagram illustrating an example of a resonator of an acoustic wave device according to a fourth embodiment.

FIG. 10 is a schematic diagram illustrating an example of a resonator of an acoustic wave device according to a fifth embodiment.

FIG. 11 is a cross-sectional view of a module to which an acoustic wave device according to a sixth embodiment is applied.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

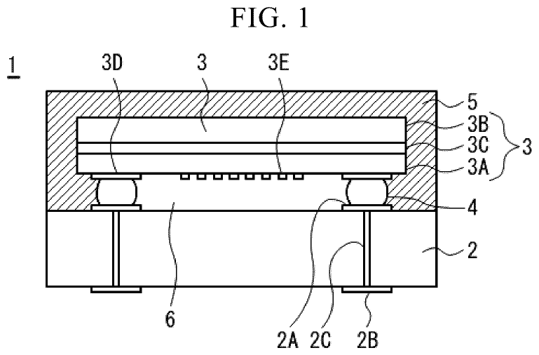

FIG. 1 is a cross-sectional view of an acoustic wave device according to a first embodiment.

As shown in FIG. 1, an acoustic wave device 1 includes a wiring substrate 2, a chip substrate 3, a plurality of bumps 4, and a sealing portion 5.

The wiring substrate 2 is a multilayer substrate made of resin. For example, the wiring substrate 2 is a low-temperature co-fired ceramic (LTCC) multilayer substrate that includes a plurality of dielectric layers. For example, the wiring substrate 2 includes a passive element (not shown) such as a capacitor or an inductor.

In FIG. 1, the upper surface of the wiring substrate 2 is a component mounting surface. A plurality of conductive pads 2A are formed on the upper surface of the wiring substrate 2. The plurality of conductive pads 2A may be formed of copper for example. The lower surface of the wiring substrate 2 is an attachment surface to a mother substrate or the like. A plurality of conductive pads 2B are formed on the lower surface of the wiring substrate 2. The plurality of conductive pads 2B may be formed of copper for example. A plurality of inner conductors 2C are embedded in the wiring substrate 2. The plurality of inner conductors 2C are formed of copper for example. Each of the inner conductors 2C electrically connects the conductive pad 2A and the conductive pad 2B corresponding to each other.

The chip substrate 3 is opposed to the wiring substrate 2. For example, the chip substrate 3 includes a piezoelectric substrate 3A, a support substrate 3B, and a low acoustic velocity layer 3C. The piezoelectric substrate 3A is disposed on the lower side of the chip substrate 3 in FIG. 1. The piezoelectric substrate 3A is formed of lithium tantalate, lithium niobate, or the like. The support substrate 3B is disposed on the upper side of the chip substrate 3. For example, the support substrate 3B is a polycrystalline substrate. For example, the polycrystalline substrate is C-axis oriented. For example, the support substrate 3B may be formed of silicon, alumina, spinel, quartz, or the like. The support substrate 3B can be made of glass. The low acoustic velocity layer 3C is disposed between the piezoelectric substrate 3A and the support substrate 3B. For example, the low acoustic velocity layer 3C is formed of silicon dioxide or the like.

A first filter and a second filter are formed on the main surface (lower surface in FIG. 1) of the chip substrate 3 for example. The first filter is a surface acoustic wave filter. The first filter is a transmission filter. The second filter is a surface acoustic wave filter. The second filter is a reception filter.

The transmission filter is formed such that an electrical signal of a desired frequency band can pass through. For example, the transmission filter includes a ladder-type filter including a plurality of series resonators and a plurality of parallel resonators.

The reception filter is formed such that an electrical signal of a desired frequency band can pass through. For example, the reception filter includes a ladder-type filter including a plurality of series resonators, a plurality of parallel resonators and a multimode resonator.

For example, the chip substrate 3 includes wiring patterns 3D and a plurality of electrodes 3E. The plurality of electrodes 3E are Interdigital Transducer (IDT) electrodes including comb-shaped electrode fingers.

Each of the plurality of bumps 4 is gold, a conductive adhesive and a solder, or the like. For example, the height of the bump 4 is 10 μm to 50 μm. Each of the plurality of bumps 4 electrically connects the conductive pads 2A and the wiring patterns 3D at corresponding positions.

The sealing portion 5 hermetically seals the chip substrate 3 together with the wiring substrate 2 while leaving a space 6 between the wiring substrate 2 and the chip substrate 3. For example, the sealing portion 5 is formed of an insulator such as synthetic resin. The synthetic resin is an epoxy resin, polyimide, or the like.

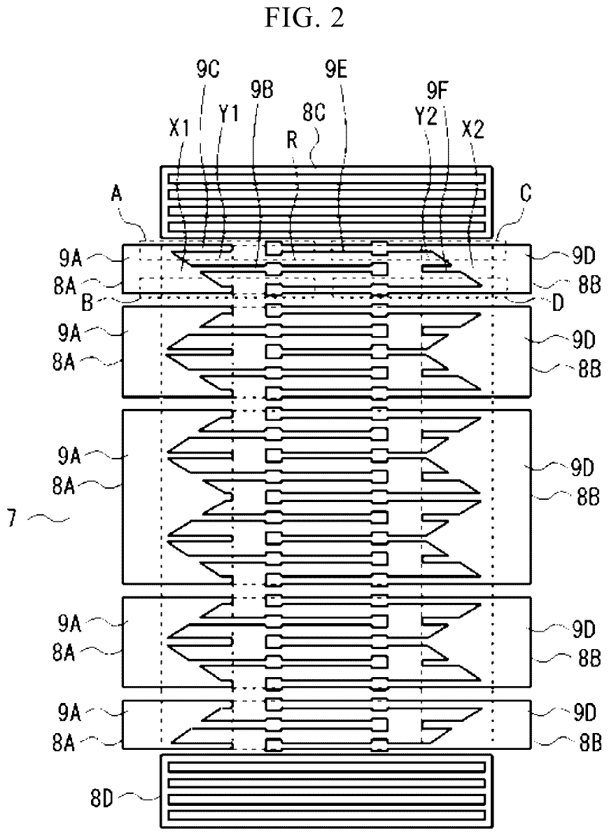

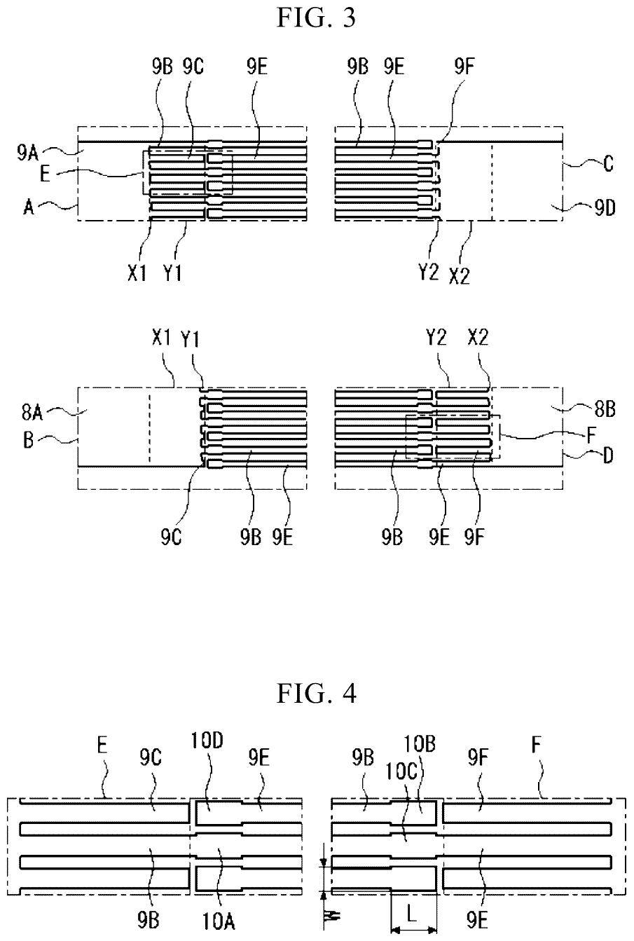

Next, an example of the resonator will be described with reference to FIG. 2 to FIG. 4. FIG. 2 is a diagram illustrating an example of the resonator of the acoustic wave device according to the first embodiment. FIG. 3 is an enlarged view of a main portion of FIG. 2. FIG. 4 is an enlarged view of portions E and F of FIG. 3.

A resonator 7 is a multimode SAW (Surface Acoustic Wave) resonator in FIG. 2. The resonator 7 includes plural pairs of IDT electrodes (five pairs in FIG. 2) and a pair of reflectors 8C and 8D. The plural pairs of IDT electrodes and the pair of reflectors 8C and 8D are formed on the other side of the support substrate 3B (not shown in FIG. 2) in the piezoelectric substrate 3A (not shown in FIG. 2). The plural pairs of IDT electrodes are arranged side by side. The reflector 8C adjoins one side of the plural pairs IDT electrodes (upper side in FIG. 2). The reflector 8D adjoins the other side of the plural pairs IDT electrodes (lower side in FIG. 2).

For example, the plural pairs of IDT electrodes and the pair of reflectors 8C and 8D are made of an alloy of aluminum and copper. For example, the plural pairs of IDT electrodes and the pair of reflectors 8C and 8D may be made of a suitable metal such as titanium, palladium, silver or an alloy thereof. For example, the plural pairs of IDT electrodes and the pair of reflectors 8C and 8D are made of a stacked metal film in which a plurality of metal layers are stacked. For example, the plural pairs of IDT electrodes and the pair of reflectors 8C and 8D are deposited and patterned in the same manner as the wiring patterns 3D (not shown in FIG. 2).

The plural pairs of IDT electrodes and the pair of reflectors 8C and 8D excite surface acoustic waves. Specifically, the plural pairs of IDT electrodes and the pair of reflectors 8C and 8D generate main-mode wave and transverse-mode wave when power is applied.

Each pair of IDT electrodes includes a first IDT electrode 8A a second IDT electrode 8B. The first IDT electrode 8A and the second IDT electrode 8B face each other. The first IDT electrode 8A includes a first busbar 9A, a plurality of first electrode fingers 9B and a plurality of first dummy electrodes 9C. The second IDT electrode 8B includes a second busbar 9D, a plurality of second electrode fingers 9E, and a plurality of second dummy electrodes 9F. IDT electrodes at the middle portion include more electrode fingers 9B, second electrode fingers 9E, first dummy electrodes 9C and second dummy electrodes 9F than IDT electrodes at end side portion include.

The first busbar 9A includes a first inclined section X1. In the middle IDT electrode, the first inclined section X1 is inclined in a direction away from the second busbar 9D and then inclined in a direction toward the second busbar 9D from the middle portion to one end portion and the other end portion of the first busbar 9A. In the two IDT electrodes on both sides of the middle IDT electrode, the first inclined portion X1 is inclined in a direction toward the second busbar 9D from the middle portion to one end portion and the other end portion of the first busbar 9A. In the two IDT electrodes at the outermost, the first inclined section X1 is inclined in a direction away from the second busbar 9D and away from the adjacent IDT electrodes.

The first busbar 9A and the second busbar 9D face each other. The second busbar 9D includes a second inclined section X2. In the middle IDT electrode, the second inclined section X2 is inclined in a direction toward to the first busbar 9A and then inclined in a direction away from the first busbar 9A from the middle portion to one end portion and the other end portion of the second busbar 9D. In the two IDT electrodes on both sides of the middle IDT electrode, the second inclined portion X2 is inclined in a direction away from the first busbar 9A from the middle portion to one end portion and the other end portion of the second busbar 9D. In the two IDT electrodes at the outermost, the second inclined section X2 is inclined in a direction toward to the first busbar 9A as away from the adjacent IDT electrodes.

The plurality of first electrode fingers 9B are connected to the side of the second busbar 9D in the first busbar 9A. The plurality of first electrode fingers 9B are arranged in the longitudinal direction. The plurality of first electrode fingers 9B are formed so as to extend from the first busbar 9A to the electrode finger region R. The plurality of second electrode fingers 9E are connected to the side of the first busbar 9A in the second busbar 9D. The plurality of second electrode fingers 9E are arranged in the longitudinal direction. The plurality of second electrode fingers 9E are formed so as to extend from the second busbar 9D to the electrode finger region R.

The plurality of first dummy electrodes 9C are connected to the side of the second busbar 9D in the first busbar 9A. The plurality of first dummy electrodes 9C are formed in a first dummy electrode region Y1. The plurality of second dummy electrodes 9F are connected to the side of the first busbar 9A in the second busbar 9D. The plurality of second dummy electrodes 9F are formed in a second dummy electrode region Y2.

FIG. 3 (as indicated by A) is an enlarged view of upper ends of the first IDT electrode 8A in the uppermost of FIG. 2. Specifically, A of FIG. 3 is a detailed view of part A of FIG. 2. FIG. 3 (as indicated by B) is an enlarged view of lower ends of the first IDT electrode 8A in the uppermost of FIG. 2. Specifically, B of FIG. 3 is a detailed view of part A of FIG. 2. FIG. 3 (as indicated by C) is an enlarged view of upper ends of the second IDT electrode 8B in the uppermost of FIG. 2. Specifically, C of FIG. 3 is a detailed view of part C of FIG. 2. FIG. 3 (as indicated by D) is an enlarged view of lower ends of the second IDT electrode 8B in the uppermost of FIG. 2. Specifically, D of FIG. 3 is a detailed view of part D of FIG. 2

As shown in FIG. 3, the plurality of first dummy electrodes 9C face the plurality of second electrode fingers 9E, respectively. The lengths of the plurality of first dummy electrodes 9C are continuously changed from one end portion to the other end portion of the first inclined section X1 of the first busbar 9A.

As shown in FIG. 2, the change in directionality of the IDT electrode at the middle portion is more frequent than that of IDT electrode at the end side portion when the lengths of the plurality of first dummy electrodes 9C change continuously from one end portion to the other end portion of the first busbar 9A. Specifically, in the middle IDT electrode, the lengths of the plurality of first dummy electrodes 9C increase continuously from the middle portion to one end portion and the other end portion of the first busbar 9A, and then decrease continuously. In the two IDT electrodes on both sides of the middle IDT electrode, the lengths of the plurality of first dummy electrodes 9C decrease continuously from the middle portion to one end and the other end of the first busbar 9A. In the two IDT electrodes at the outermost, the lengths of the plurality of the first dummy electrodes 9C increase continuously as away from the adjacent IDT electrodes.

As shown in FIG. 3, the plurality of second dummy electrodes 9F face the plurality of first electrode fingers 9B, respectively. The lengths of the plurality of second dummy electrodes 9F in inverse correlation with the plurality of the first dummy electrodes 9C are continuously changed from one end portion to the other end portion of the second inclined portion X2 of the second busbar 9D.

As shown in FIG. 2, the change in directionality of the IDT electrode at the middle portion is more frequent than that of IDT electrode at the end side portion when the lengths of the plurality of second dummy electrodes 9F change continuously from one end portion to the other end portion of the second busbar 9D. Specifically, in the middle IDT electrode, the lengths of the plurality of second dummy electrodes 9F decrease continuously from the middle portion to one end portion and the other end portion of the second busbar 9D, and then increase continuously. In the two IDT electrodes on both sides of the middle IDT electrode, the lengths of the plurality of second dummy electrodes 9F increase continuously from the middle portion to one end and the other end of the second busbar 9D. In the two IDT electrodes at the outermost, the lengths of the plurality of the second dummy electrodes 9F decrease continuously as away from the adjacent IDT electrodes.

When the wavelength of the surface acoustic wave is λ, the length of the uppermost first dummy electrode 9C is set to λ. The length of the lowermost first dummy electrode 9C is set to approximately 0. The length of the uppermost second dummy electrode 9F is set to approximately λ. The length of the lowermost second dummy 9F is set to 0.

As shown in FIG. 4 (as indicated by E), each of the plurality of first electrode fingers 9B includes first base side wide-width regions 10A. The first base side wide-width regions 10A are formed at base portions of the first electrode fingers 9B. As shown in FIG. 4 (as indicated by F), each of the plurality of first fingers 9B includes first distal side wide-width regions 10B. The first distal side wide-width regions 10B are formed at the distal side of the first electrode fingers 9B.

As shown in FIG. 4 (as indicated by F), each of the plurality of second electrode finger 9E includes second base side wide-width regions 10C. The second base side wide-width regions 10C are formed at base portions of the second electrode fingers 9E. As shown in FIG. 4 (as indicated by E), each of the plurality of second electrode finger 9E includes second distal side wide-width regions 10D. The second distal side wide-width regions 10D are formed at the distal side the second electrode fingers 9E.

As shown in FIG. 4 (as indicated by E), the first base side wide-width regions 10A adjoin to the second distal side wide-width regions 10D of the adjacent second electrode finger 9E. As shown in FIG. 4 (as indicated by F), the second base side wide-width regions 10C adjoin the first distal side wide-width regions 10B of the adjacent first electrode fingers 9B.

For example, the length L of the aperture length is set to between 0.50λ and 1.75λ when the wavelength of the surface acoustic wave is A in the first base side wide-width regions 10A, the first distal side wide-width regions 10B, the second base side wide-width regions 10C and the second distal side wide-width regions 10D. For example, the width W of the acoustic wave in the traveling direction is set to the width of the set magnification between 1.1 and 1.4 times in corresponding electrode finger. In the present embodiment, the length L of the aperture length is set to λ. The width W in the traveling direction of the acoustic wave is set to 1.2 times the width of the corresponding electrode finger.

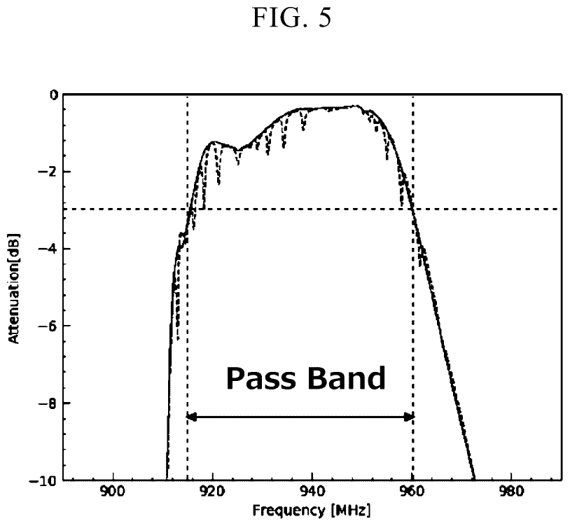

Next, characteristics of the resonator 7 will be described with reference to FIG. 5. FIG. 5 is a diagram illustrating the characteristics of the resonator of the acoustic wave device according to the first embodiment and the resonator of the comparative example. The horizontal axis of FIG. 5 represents frequency (MHz). The vertical axis of FIG. 5 represents attenuation (dB). In FIG. 5, the pass band is set to a band in which the absolute value of the attenuation is equal to or less than 3 dB.

A solid line in FIG. 5 represents characteristics of the resonator 7 of the acoustic wave device 1 according to the first embodiment. The number of pairs of the sum of the plurality of pairs of electrodes in the resonator 7 is 95 pairs. Specifically, the number of pairs of the IDT electrodes at the middle portion is set to 42.5 pairs. The number of the pairs of the two IDT electrodes on both sides of the middle IDT electrode is set to 22 pairs. The number of the two IDT electrodes at the outermost is set to 7.5 pairs. The aperture length of each IDT is set to 21λ. The duty ratio (ratio of the width of the electrode finger to the pitch of the electrode finger) is set to 50%, pitch modulation or the like is added. The dotted line in FIG. 5 shows the characteristics of the comparative example in which the inclined portion of the busbar and the wide-width regions of the electrode fingers are removed from the resonator 7 of the acoustic wave device 1 according to the first embodiment.

As shown by the broken line in FIG. 5, the absolute value of the attenuation amount in the comparative example locally increases within the passband of the comparative example. On the other hand, as shown by the solid line of FIG. 5, the absolute value of the attenuation amount in the resonator 7 of the acoustic wave device 1 according to the first embodiment is suppressed from locally increasing within the passband of the resonator 7. This indicates that the transverse-mode spurious of the resonator 7 is suppressed within the passband.

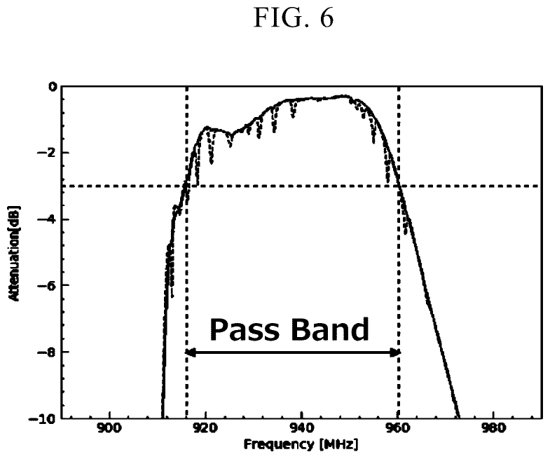

Next, the difference in characteristics due to the difference of wide-width regions will be described with reference to FIG. 6. FIG. 6 is a diagram illustrating the characteristics of the resonator including a busbar with the same inclined section as the resonator of the acoustic wave device according to the first embodiment and the different wide-width regions with the same length of the dummy electrode. The horizontal axis and the vertical axis of FIG. 6 are the same as those of FIG. 5. The setting of the passband in FIG. 6 is the same as the setting in FIG. 5.

The solid line in FIG. 6 represents the characteristics of the resonator including a busbar with the same inclined section as the resonator 7 of the acoustic wave device according to the first embodiment and different wide-width regions with the same length of the dummy electrode. The length L of the aperture length is set to 0.75λ in the resonator corresponding to the solid line in FIG. 6. The width W in the traveling direction of the acoustic wave is set to 1.20 times the width of the corresponding electrode finger. The dotted line in FIG. 6 represents the characteristics of the comparative example the same as the dotted line in FIG. 5.

As shown in FIG. 6, the absolute value of the attenuation amount is suppressed from locally increasing within the pass band even though the size of the wide regions is slightly different. This indicates that the transverse-mode spurious of the resonator is suppressed within the pass band even though the size of the wide regions is slightly different.

According to the first embodiment described above, the first electrode fingers 9B include the first distal side wide-width regions 10B. The second electrode fingers 9E include the second distal side wide-width regions 10D. The plurality of first dummy electrodes 9C continuously change from one end portion to the other end portion of the first busbar 9A. Therefore, transverse-mode spurious within the pass band can be suppressed more reliably.

The change in directionality of the IDT electrode at the middle portion is more frequent than that of IDT electrode at the end side portion when the lengths of the plurality of first dummy electrodes 9C change continuously from one end portion to the other end portion of the first busbar 9A. Therefore, transverse-mode spurious within the pass band can be suppressed more reliably.

The support substrate 3B is a polycrystalline substrate formed of silicon, alumina, spinel, or the like. Therefore, transverse-modes spurious within the pass band can be suppressed more reliably even in the resonator 7 in which the polycrystalline substrate is used.

The polycrystalline substrate as the support substrate 3B is C-axis oriented. Therefore, transverse-modes spurious within the pass band can be suppressed more reliably even in the resonator 7 in which the C-axis oriented polycrystalline substrate is used.

The low acoustic velocity layer 3C is disposed between the piezoelectric substrate 3A and the support substrate 3B. Therefore, transverse-modes spurious within the pass band can be suppressed more reliably even in the resonator 7 including the low acoustic velocity layer 3C.

The first electrode fingers 9B include the first base side wide-width regions 10A. The second electrode fingers 9E include the second base side wide-width regions 10C. Therefore, transverse-modes spurious within the pass band can be suppressed more reliably.

The first base side wide-width regions 10A adjoin the second distal side wide-width regions 10D of the adjacent second electrode finger 9E. The second base side wide-width regions 10C adjoin the first distal side wide-width regions 10B of the adjacent first electrode fingers 9B. Therefore, transverse-modes spurious within the pass band can be suppressed more reliably.

The plurality of second dummy electrodes 9F continuously change from one end portion to the other end portion of the second busbar 9D in an inverse correlation with the plurality of first dummy electrodes 9C. Therefore, transverse-modes spurious within the pass band can be suppressed more reliably.

The length L of the aperture length is set to between 0.50λ and 1.75λ in the first base side wide-width regions 10A, the first distal side wide-width regions 10B, the second base side wide-width regions 10C and the second distal side wide-width regions 10D. Therefore, transverse-modes spurious within the pass band can be suppressed more reliably.

The length L of the aperture length may be set to between 0.50λ and 1.75λ in at least one of the first base side wide-width regions 10A, the first distal side wide-width regions 10B, the second base side wide-width regions 10C and the second distal side wide-width regions 10D. In this case, transverse-modes spurious within the pass band can be suppressed to some extent.

The width W of the acoustic wave in the traveling direction is set to the width of the set magnification between 1.1 and 1.4 times in corresponding electrode finger in the first base side wide-width regions 10A, the first distal side wide-width regions 10B, the second base side wide-width regions 10C and the second distal side wide-width regions 10D. Therefore, transverse-modes spurious within the pass band can be suppressed more reliably.

The width W of the acoustic wave in the traveling direction is set to the width of the set magnification between 1.1 and 1.4 times of the corresponding electrode finger in at least one of the first base side wide-width regions 10A, the first distal side wide-width regions 10B, the second base side wide-width regions 10C and the second distal side wide-width regions 10D. In this case, transverse-modes spurious within the pass band can be suppressed more reliably.

The lengths of the plurality of first dummy electrodes 9C may be continuously changed from one end portion to the other end portion of the first busbar 9A at least one of a plurality of the pairs of ITD electrodes. In this case, transverse-modes spurious within the pass band can be suppressed more reliably.

The lengths of the plurality of the second dummy electrodes 9F may be continuously changed from one end portion to the other end portion of the second busbar 9D in correlation with the plurality of first dummy electrodes 9C. In this case, transverse-modes spurious within the pass band can be suppressed more reliably.

### Second Embodiment

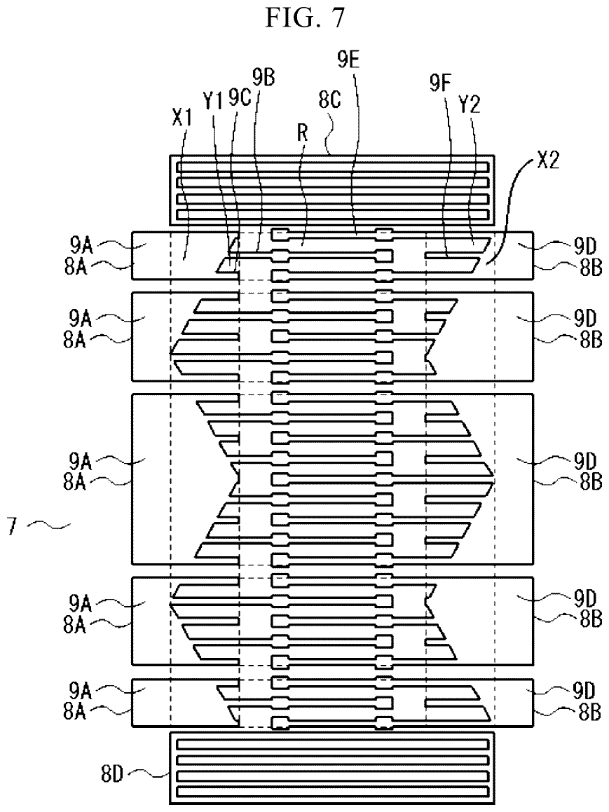

FIG. 7 is schematic diagram illustrating an example of a resonator of an acoustic wave device according to a second embodiment. The same or corresponding parts with the first embodiment are denoted by the same reference numerals. Duplicate descriptions of such portions may be simplified or omitted.

As shown in FIG. 7, in the second embodiment, the lengths of the first dummy electrodes 9C change continuously across the adjacent IDT electrodes in the direction of arrangement of the plurality of the pairs of IDT electrodes.

Specifically, the lengths of the plurality of first dummy electrodes 9C increase continuously from the middle portion to one end and the other end of the first busbar 9A at the middle of ITD electrode. In the two IDT electrodes on both sides of the middle IDT electrode, the lengths of the plurality of first dummy electrodes 9C increase continuously as away from IDT electrodes at the middle, then decrease continuously. In the two IDT electrodes at the outermost, the lengths of the plurality of the first dummy electrodes 9C decrease continuously as away from the adjacent IDT electrodes.

The lengths of the plurality of second dummy electrodes 9F in an inverse correlation with the plurality of the first dummy electrodes 9C are continuously changed from one end portion to the other end portion of the second inclined portion X2 of the second busbar 9D.

According to the second embodiment described above, the transverse-mode spurious within the pass band can be suppressed more reliably as well.

### Third Embodiment

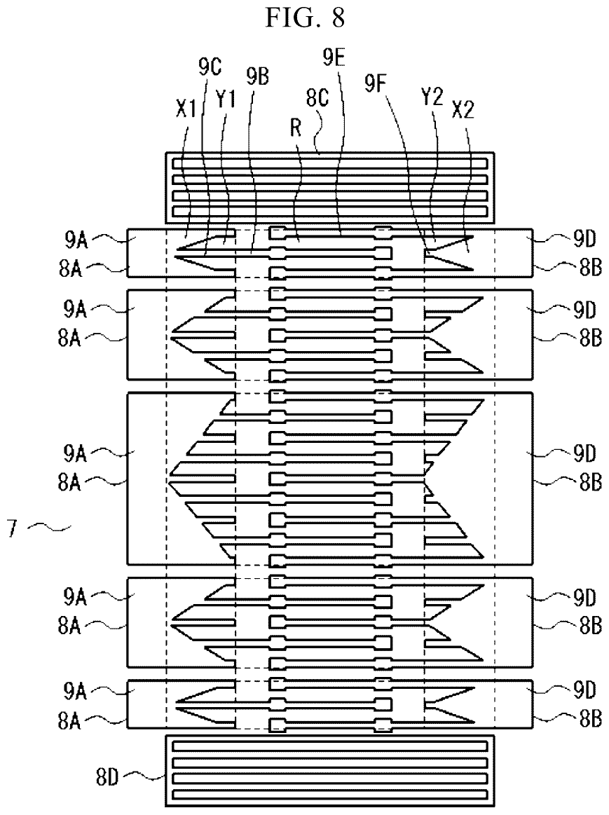

FIG. 8 is a schematic diagram illustrating an example of a resonator of an acoustic wave device according to a third embodiment. The same or corresponding parts with the first embodiment are denoted by the same reference numerals. Duplicate descriptions of such portions may be simplified or omitted.

As shown in FIG. 8, in the third embodiment, the number of changes in directionality of the plurality of pairs of the IDT electrodes is the same when the lengths of the plurality of first dummy electrodes 9C change continuously from one end portion to the other end portion of the first busbar 9A. Specifically, in the plurality of pairs of the IDT electrodes, the lengths of the plurality of first dummy electrodes 9C decrease continuously from the middle portion to one end and the other end of the first busbar 9A.

The lengths of the plurality of second dummy electrodes 9F in inverse correlation with the plurality of the first dummy electrodes 9C are continuously changed from one end portion to the other end portion of the second inclined portion X2 of the second busbar 9D.

According to the third embodiment described above, the transverse-mode spurious within the pass band can be suppressed more reliably as well.

### Fourth Embodiment

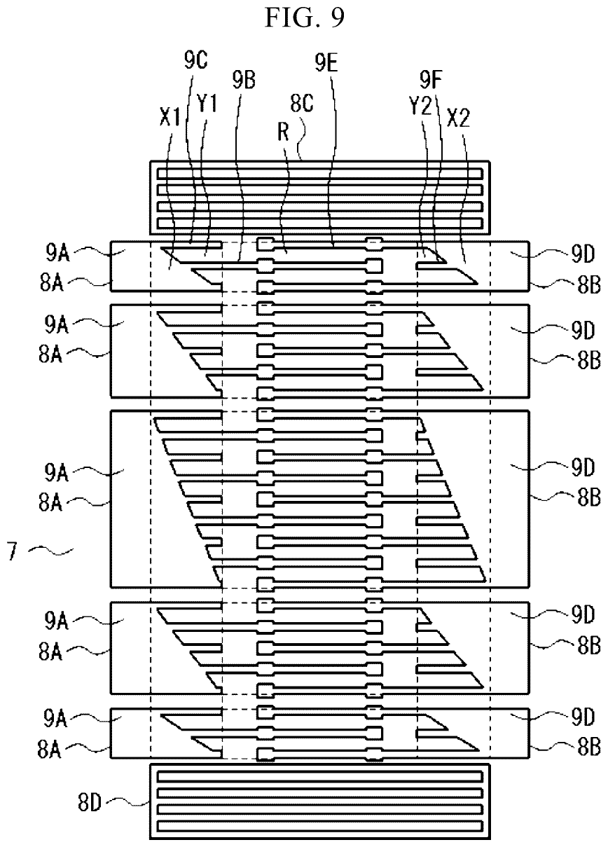

FIG. 9 is a schematic diagram illustrating an example of a resonator of an acoustic wave device according to a fourth embodiment. The same or corresponding parts with the first embodiment are denoted by the same reference numerals. Duplicate descriptions of such portions may be simplified or omitted.

As shown in FIG. 9, in the fourth embodiment, the direction is the same in the plurality of pairs of the IDT electrodes when the lengths of the plurality of first dummy electrodes 9C change continuously from one end portion to the other end portion of the first busbar 9A. Specifically, the lengths of the plurality of first dummy electrodes 9C decrease continuously from one end to the other end of the first busbar 9A.

The lengths of the plurality of second dummy electrodes 9F in an inverse correlation with the plurality of the first dummy electrodes 9C are continuously changed from one end portion to the other end portion of the second inclined portion X2 of the second busbar 9D.

According to the fourth embodiment described above, the transverse-mode spurious within the pass band can be suppressed more reliably as well.

### Fifth Embodiment

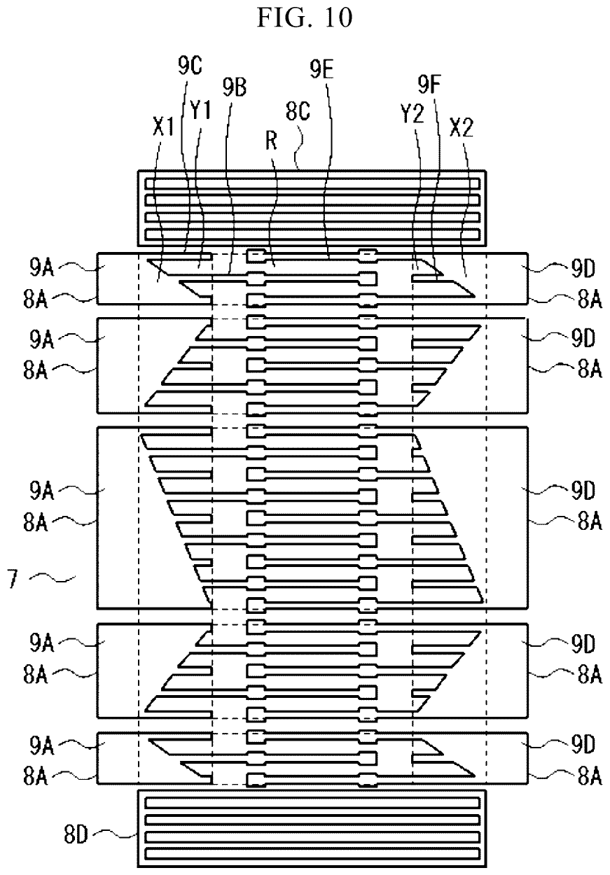

FIG. 10 is a schematic diagram illustrating an example of a resonator of an acoustic wave device according to a fifth embodiment. The same or corresponding parts with the first embodiment are denoted by the same reference numerals. Duplicate descriptions of such portions may be simplified or omitted.

As shown in FIG. 10, in the fifth embodiment, the direction differs in the adjacent IDT electrodes when the lengths of the plurality of first dummy electrodes 9C change continuously from one end portion to the other end portion of the first busbar 9A. Specifically, in the first IDT electrode 8A adjacent to the first IDT electrode 8A where the lengths of the plurality of first dummy electrodes 9C decrease continuously from one end to the other end of the first busbar 9A, the lengths of the plurality of first dummy electrodes 9C continuously increase from one end portion to the other end portion of the first busbar 9A

The lengths of the plurality of second dummy electrodes 9F in an inverse correlation with the plurality of the first dummy electrodes 9C are continuously changed from one end portion to the other end portion of the second inclined portion X2 of the second busbar 9D.

According to the fifth embodiment described above, the transverse-mode spurious within the pass band can be suppressed more reliably as well.

### Sixth Embodiment

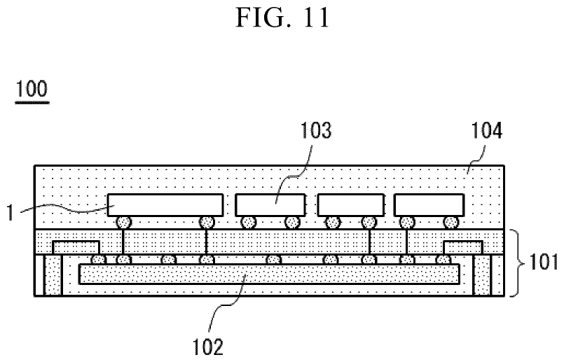

FIG. 11 is a cross-sectional view of a module to which an acoustic wave device according to a sixth embodiment is applied. The same or corresponding parts with the first embodiment are denoted by the same reference numerals. Duplicate descriptions of such portions may be simplified or omitted.

A module 100 includes a wiring substrate 101, an integrated circuit component 102, the acoustic wave device 1, an inductor 103, and a sealing portion 104 in FIG. 11.

The wiring substrate 101 is equivalent to the wiring substrate 2 of the first embodiment. The integrated circuit component 102 is mounted inside the wiring substrate 101. The integrated circuit component 102 includes a switching circuit and a low noise amplifier. The acoustic wave device 1 is mounted on the main surface of the wiring substrate 101. The inductor 103 is mounted on the main surface of the wiring substrate 101. The inductor 103 is implemented for impedance matching. For example, the inductor 103 is an Integrated Passive Device (IPD). The sealing portion 104 seals a plurality of electronic components including the acoustic wave device 1.

According to the sixth embodiment described above, the module 100 includes the acoustic wave device 1. Therefore, the module 100 including the acoustic wave device 1 in which the transverse-mode spurious within the pass band is suppressed can be obtained.

While several aspects of at least one embodiment have been described, it is to be understood that various modifications and improvements will readily occur to those skilled in the art. Such modifications and improvements are intended to be part of the present disclosure and are intended to be within the scope of the present disclosure.

It is to be understood that the embodiments of the methods and apparatus described herein are not limited in application to the structural and ordering details of the components set forth in the foregoing description or illustrated in the accompanying drawings. Methods and apparatus may be implemented in other embodiments or implemented in various manners. Specific implementations are given here for illustrative purposes only and are not intended to be limiting.

The phraseology and terminology used in the present disclosure are for the purpose of description and should not be regarded as limiting. The use of “including,” “comprising,” “having,” and variations thereof herein means the inclusion of the items listed hereinafter and equivalents thereof, as well as additional items.

The reference to “or” may be construed so that any term described using “or” may be indicative of one, more than one, and all of the terms of that description.

References to front, back, left, right, top, bottom, and side are intended for convenience of description. Such references are not intended to limit the components of the present disclosure to any one positional or spatial orientation. Accordingly, the foregoing description and drawings are by way of example only.

What is claimed is:

1. An acoustic wave device comprising:
a piezoelectric substrate;
a support substrate, a first side of the support substrate bonded to the piezoelectric substrate; and
a resonator comprising a plurality of pairs of IDT electrodes arranged side by side and formed on the piezoelectric substrate that generates main-mode wave and transverse-mode wave when power is applied,
wherein at least one of the plurality of pairs of IDT electrodes comprises:
a first busbar,
a second busbar opposed to the first busbar,
a plurality of first electrode fingers connected to a side of the second busbar in the first busbar,
a plurality of second electrode fingers connected to a side of the first busbar in the second busbar,
a plurality of first dummy electrodes connected to the side of the second busbar in the first busbar and opposed to the plurality of second electrode fingers,
and a plurality of second dummy electrodes connected to the side of the first busbar in the second busbar and opposed to the plurality of first electrode fingers,
wherein distal ends of the plurality of first electrode fingers comprise first distal side wide-width regions, distal ends of the plurality of second electrode fingers comprise second distal side wide-width regions, and lengths of the plurality of first dummy electrodes change continuously from one end portion to the other end portion of the first busbar.

2. The acoustic wave device according to claim 1, wherein the plurality of pairs of IDT electrodes comprises:
the first busbar,
the second busbar opposed to the first busbar,
the plurality of first electrode fingers connected to the side of the second busbar in the first busbar,
the plurality of second electrode fingers connected to the side of the first busbar in the second busbar,
the plurality of first dummy electrodes connected to the side of the second busbar in the first busbar and opposed to the plurality of second electrode fingers, and
the plurality of second dummy electrodes connected to the side of the first busbar in the second busbar and opposed to the plurality of first electrode fingers respectively,
wherein the distal ends of the plurality of first electrode fingers comprise first distal side wide-width regions, the distal ends of the plurality of second electrode fingers comprise second distal side wide-width regions, IDT electrodes at a middle portion comprise more first electrode fingers, second electrode fingers, first dummy electrodes and second dummy electrodes than IDT electrodes at the end side portion comprise, and the lengths of the plurality of first dummy electrodes change continuously from one end portion to the other end portion of the first busbar.

3. The acoustic wave device according to claim 2, wherein a change in directionality of the IDT electrodes at the middle portion is more frequent than that of the IDT electrodes at the end side portion when the lengths of the plurality of first dummy electrodes change continuously from one end portion to the other end portion of the first busbar.

4. The acoustic wave device according to claim 2, wherein the lengths of the first dummy electrodes change continuously across the adjacent IDT electrodes in a direction of arrangement of the plurality of the pairs of IDT electrodes.

5. The acoustic wave device according to claim 2, wherein the number of changes in directionality of the plurality of pairs of the IDT electrodes is the same when the lengths of the plurality of first dummy electrodes change continuously from the one end portion to the other end portion of the first busbar.

6. The acoustic wave device according to claim 2, wherein a direction of arrangement is the same in the plurality of pairs of the IDT electrodes when the lengths of the plurality of first dummy electrodes change continuously from the one end portion to the other end portion of the first busbar.

7. The acoustic wave device according to claim 2, the direction of arrangement is different in the adjacent IDT electrodes when the lengths of the plurality of first dummy electrodes change continuously from the one end portion to the other end portion of the first busbar.

8. The acoustic wave device according to claim 1, wherein lengths of the plurality of second dummy electrodes in an inverse correlation with the plurality of the first dummy electrodes continuously change from one end portion to the other end portion of the second busbar.

9. The acoustic wave device according to claim 1, wherein lengths of the plurality of second dummy electrodes in correlation with the plurality of the first dummy electrodes continuously change from one end portion to the other end portion of the second busbar.

10. A module comprising the acoustic wave device according to claim 1.
